(19) United States
(12) Patent Application Publication
(10) Pub. No.: US 2025/0341591 A1
(43) Pub. Date: Nov. 6, 2025

(54) METHODS AND SYSTEMS FOR DETECTING ELECTRICAL LEAKAGE

(71) Applicant: Electrovaya Inc., Mississauga (CA)

(72) Inventors: William Keith Baker, Inglewood (CA); Abdolhassan Shahrbanoozadeh, Brampton (CA)

(21) Appl. No.: 19/065,352

(22) Filed: Feb. 27, 2025

Related U.S. Application Data
(60) Provisional application No. 63/642,516, filed on May 3, 2024.

(51) Int. Cl. G01R 31/52; H01M 10/42; H01M 10/48

(52) U.S. Cl. CPC G01R 31/52; H01M 10/4285; H01M 10/482

(57) ABSTRACT

ochemical cells, a housing frame configured to house the plurality of electrochemical cells therewithin, and a sensing module configured to detect a leakage between the plurality of electrochemical cells and the housing frame. The sensing module may include a current limiter electrically coupled to a cathode or an anode of one or more of the electrochemical cells and the housing frame, and an ammeter configured to measure a current between the current limiter and the electrochemical cells. The system may include a circuit powered by an isolated power supply to measure the voltage generated by a leakage current flowing through the current limiter.

[symbol]

### CROSS REFERENCE TO RELATED APPLICATION

This application claims priority to U.S. Patent Application No. 63/642,516, filed May 3, 2024, all of which is incorporated by reference herein in its entirety.

### FIELD OF INVENTION

The disclosure relates to electric power sources (e.g., electrochemical energy storage devices) including rechargeable lithium-ion batteries, and more particularly related to a system, a device, and a method for detecting electrical leakage from the power sources.

### BACKGROUND

Power sources, such as battery units for powering electric vehicles, are electrically isolated from a container, or a housing frame of the batteries (or generally referred to as electrochemical cells), and the vehicles in which they reside. Failure of insulation, either in wiring or in chemical leakage of electrolyte from any battery component, such as a battery cell, may result in a potentially hazardous voltage on the housing frame, which is typically a metal frame, with respect to the anodes or cathodes of the batteries. Thus, there is a need for a method, a device, or a system for detecting the breakdown of the insulation (e.g., a leakage) between the power source, i.e., the battery, and the housing frame that houses the battery.

### BRIEF DESCRIPTION OF THE DRAWINGS

For a more complete understanding of the principles disclosed herein, and the advantages thereof, reference is now made to the following descriptions taken in conjunction with the accompanying drawings, in which:

FIG. 1 illustrates an embodiment of an electrical energy storage system as a battery module, in accordance with various embodiments.

FIG. 2 illustrates a circuit model of an electrical leakage in an electrical energy storage system, in accordance with various embodiments.

FIG. 3 shows a circuit model of a leakage detection mechanism in an electrical energy storage system, in accordance with various embodiments.

FIG. 4 is a circuit diagram showing an embodiment of a current limiter in an electrical energy storage system, in accordance with various embodiments.

FIG. 5 is a circuit diagram showing an embodiment of a sensing module with a leakage detection mechanism in an electrical energy storage system, in accordance with various embodiments.

FIG. 6 is a circuit diagram showing another embodiment of a sensing module with a leakage detection mechanism in an electrical energy storage system, in accordance with various embodiments.

FIG. 7 illustrates a method for detecting a leakage in an electrical energy storage system, in accordance with various embodiments.

FIG. 8 illustrates a block diagram of a processor (computer system) used in the electrical energy storage systems of FIGS. 1, 2, 3, 4, 5, and 6, and the method of FIG. 7, in accordance with various embodiments.

It is to be understood that the figures are not necessarily drawn to scale, nor are the objects in the figures necessarily drawn to scale in relationship to one another. The figures are depictions that are intended to bring clarity and understanding to various embodiments of apparatuses, systems, and methods disclosed herein. Wherever possible, the same reference numbers will be used throughout the drawings to refer to the same or like parts. Moreover, it should be appreciated that the drawings are not intended to limit the scope of the present teachings in any way.

### DETAILED DESCRIPTION

The following shall be a detailed description of the drawings which are given for the purposes of illustrating the preferred embodiments of the present invention, and not for the purpose of limiting the same. In accordance with various embodiments, a system and a method for detecting an electrical leakage are provided. In particular, a system, a device, and a method for detecting a breakdown of electrical insulation in an electrochemical energy storage device having a housing or a frame that contains the electrochemical energy storage device. In one or more embodiments, the disclosed system may include a plurality of electrochemical cells and a housing frame configured to house the electrochemical cells within the housing frame. In one or more embodiments, the system may include a sensing module that includes a current limiter and an ammeter, where the current limiter may be electrically coupled to a cathode or an anode of one or more of the electrochemical cells and the housing frame. The ammeter may be used to measure a current between the current limiter and the plurality of electrochemical cells. In accordance with various embodiments, the sensing module in the system may be configured to detect a leakage, such as an electrical leakage, between one or more of the electrochemical cells and the housing frame.

In one or more embodiments, a method of detecting an electrical leakage may include connecting a current limiter between the housing frame and an anode (or a cathode) of the electrochemical cells such that a leakage current may flow from the electrochemical cells to the housing frame. The method may include measuring the leakage current in order to determine the degree of leakage. In various embodiments, the leakage current may be measured with both anode and cathode connections. In one or more embodiments, an exact location of leakage, i.e., insulation breakdown, may be unknown. In accordance with one or more embodiments, the disclosed system/method may be configured to detect a leakage current below 2 milliamperes (mA).

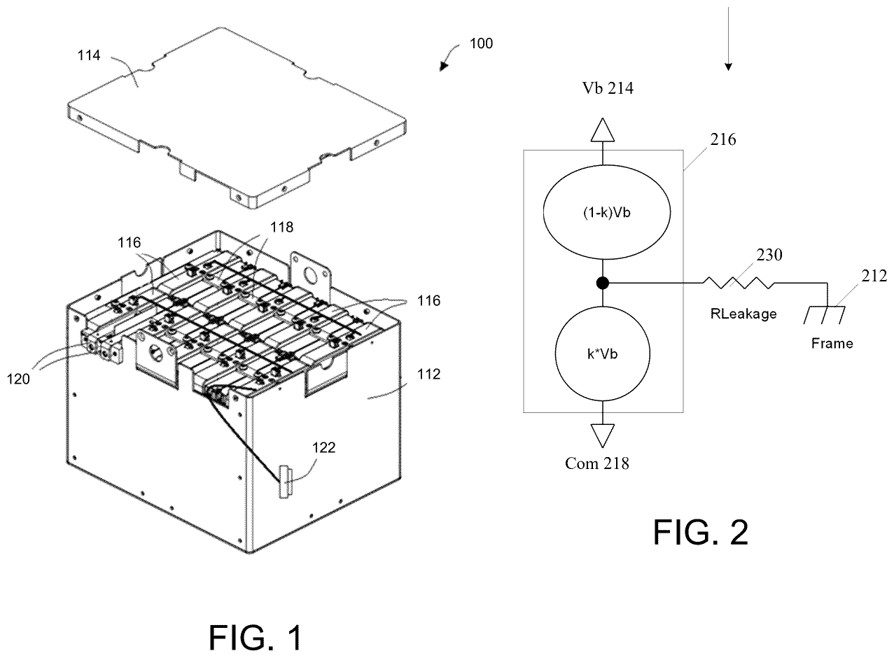

FIG. 1 illustrates an embodiment of an electrical energy storage system 100, such as a battery module, in accordance with various embodiments. As illustrated in FIG. 1, the electrical energy storage system 100 includes one or more electrochemical cells 116 connected in series and/or parallel and are contained inside a housing frame 112 (referred to herein as a housing, a frame, or simply an enclosure) and enclosed by a lid 114 (removable or otherwise), in accordance with one or more embodiments. In some embodiments, the electrical energy storage system 100 includes the electrochemical cells 116 connected in series by one or more bus bars 118 located in the housing frame 112. As illustrated in FIG. 1, the electrical energy storage system 100 includes cell-to-cell connections 120 (to one or more anodes and cathodes of the electrochemical cells 116) and a cable assembly 122, which can be configured to provide access to individual electrochemical cells 116 for measuring, for example, cell voltage and/or temperature. In one or more embodiments, cell connections 120 are to be isolated from the housing frame 112 and the lid 114 in the electrical energy storage system 100. In some scenario, a failure of insulation (i.e., insulation breakdown) can occur between the housing frame 112 and/or the lid 114, and the electrochemical cells 116. This insulation breakdown or an electrical leakage, can occur via an electrical shortage in one of the connections 120, or a liquid leakage, e.g., a leakage of electrolyte from one of the electrochemical cells 116. In one or more embodiments, the insulation breakdown may result in a loss of the electrical isolation between the electrochemical cells 116 and the housing frame 112 and/or the lid 114.

FIG. 2 illustrates a circuit model of an electrical leakage in an electrical energy storage system 200, in accordance with various embodiments. As depicted in FIG. 2, the electrical energy storage system 200 includes a plurality of electrochemical cells 216 that are disposed within a housing frame 212. The circuit model shown in FIG. 2 illustrates an electrical leakage 230 between the plurality of electrochemical cells 216 and the housing frame 212. For the plurality of electrochemical cells 216, a resistance can be shown as having a potential, designated as Vb 214, to a ground, designated as Com 218, the loss of isolation occurs at any part in the electrical energy storage system 200. In other words, it is assumed that a leakage current to the housing frame 212 occurs from some arbitrary point in a stack of the plurality of cells 216 that forms the supplying voltage of “the battery” Vb, and that leakage can be represented as a single resistance R_{Leakge} to the frame 212 from a point between the bottom-most cell cathode to the top-most cell anode as shown in FIG. 2. If k∈[0,1] represents where the isolation is lost (i.e., electrical leakage occurs) within the electrical energy storage system 200, and k*Vb can be designated as the associated voltage (with respect to the cathode Com 218) driving any leakage. Accordingly, the associated voltage (with respect to the anode Vb 214) is denoted as (1−k)*Vb. The electrical leakage 230 can be denoted as RLeakge to represent the degree of compromise of the isolation or leakage between the plurality of electrochemical cells 216 and the frame 212.

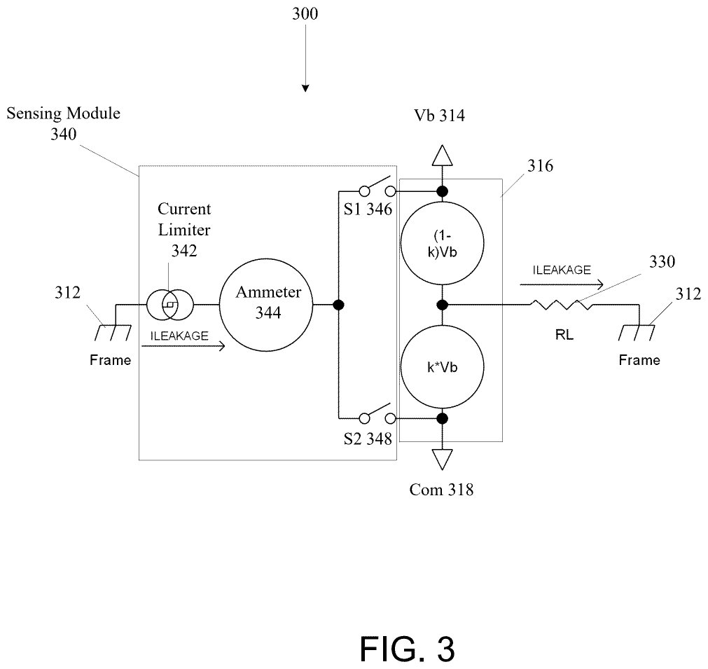

FIG. 3 shows a circuit model of a leakage detection mechanism in an electrical energy storage system 300, in accordance with various embodiments. As illustrated in FIG. 3, the electrical energy storage system 300 includes a plurality of electrochemical cells 316 that are disposed within a housing frame 312. The circuit model shown in FIG. 3 illustrates an electrical leakage 330 between the plurality of electrochemical cells 316 and the housing frame 312. Similar to the description of FIG. 2, for the plurality of electrochemical cells 316, a resistance can be shown as having a potential, designated as Vb 314, to a ground, designated as Com 318, the loss of isolation occurs at any part in the electrical energy storage system 300. If k∈[0,1] represents where the isolation is lost (i.e., electrical leakage occurs) within the electrical energy storage system 300, and k*Vb can be designated as the associated voltage (with respect to the cathode Com 318) driving any leakage. Similarly, the associated voltage (with respect to the anode Vb 314) is denoted as (1−k)*Vb. The electrical leakage 330 can be denoted as RLeakge to represent the degree of compromise of the isolation or leakage between the plurality of electrochemical cells 316 and the frame 312.

As further illustrated in FIG. 3, the electrical energy storage system 300 further includes a sensing module 340 that is coupled to the plurality of electrochemical cells 316 via relay switches S1 346 and S2 348. The sensing module 340 further includes a current limiter 342 and an ammeter 344 connected in series between the frame 312 and either an anode or a cathode of the plurality of electrochemical cells 316, as depicted in FIG. 3. When either S1 346 or S2 348 are closed, a circuit is complete or closed, and any leakage current may flow from the plurality of electrochemical cells 316 to the frame 312, which can then be measured by the ammeter 344. In accordance with one or more embodiments, the current limiter 342 has at least two functions: to limit the amount of current flow that may occur when R_{Leakge} is small, and act as a current limited source at safe levels (as per industry standards, such as for example, but not limited to, UL 60950) as the circuit is itself a leakage path to the frame 312 when a switch (either S1 346 or S2 348) is closed.

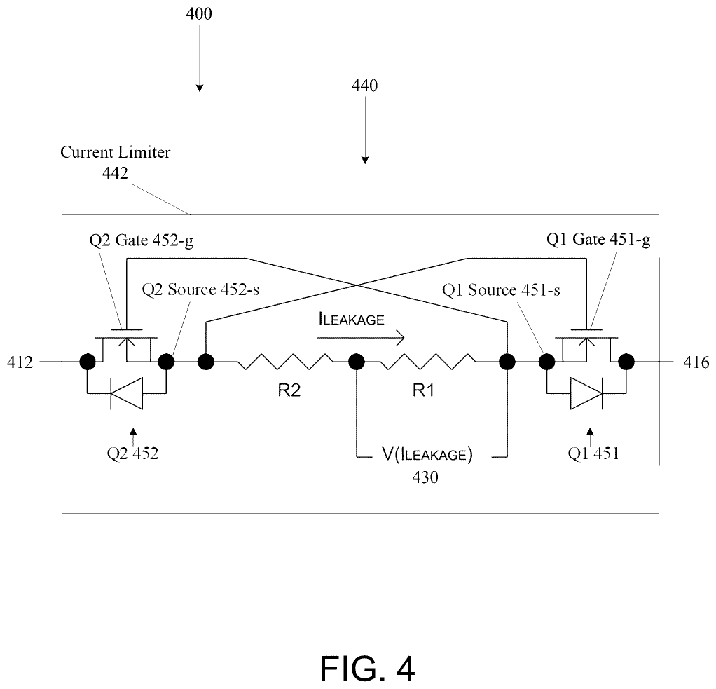

FIG. 4 is a circuit diagram showing an embodiment of a current limiter 442 in an electrical energy storage system 400, in accordance with various embodiments. As illustrated in FIG. 4, the electrical energy storage system 400 includes a sensing module 440 that is coupled to the plurality of electrochemical cells 316. The sensing module 440 includes the current limiter 442, which may be a bi-directional current limiter that incorporates a current measurement element, in accordance with one or more embodiments herein. In one or more embodiments, the current limiter 442 is electrically coupled to a housing frame 412 and a plurality of electrochemical cells 416, as depicted in FIG. 4. The current limiter 442 includes a first depletion-mode metal-oxide-semiconductor field-effect transistor (MOSFET) Q1 451 and a second depletion-mode MOSFET Q2 452, as shown in FIG. 4. In one or more embodiments, Q1 451 and Q2 452 may be N- channel MOSFETs.

The MOSFET Q1 451 has Q1 source 451-s and Q1 gate 451-g and MOSFET Q2 451 has Q2 source 452-s and Q2 gate 452-g, in one or more embodiments. In some embodiments, Q1 source 451-s of MOSFET Q1 451 and Q2 source 452-s of MOSFET Q2 452 are electrically connected to one another via R1 and R2, as shown in FIG. 4. The gates (Q1 gate 451-g and Q2 gate 452-g) of each transistor MOSFET Q1 451 and MOSFET Q2 452 are connected to the source of the other transistor. When current flows through the current limiter 442, a voltage is generated across R1 and R2, and if the voltage becomes large enough, that is, the leakage current is sufficiently large, then one transistor, either MOSFET Q1 451 or MOSFET Q2 452, will begin to turn off, limiting the current flow, in accordance with one or more embodiments described herein. The direction of the (leakage) current flow determines which transistor, MOSFET Q1 451 or MOSFET Q2 452, will switch off, in one or more embodiments. In some embodiments, the current may be limited at Vt/(R1+R2) where Vt is the threshold voltage of the MOSFET, Q1 451 or Q2 452. The leakage current can be deduced directly by measuring the voltage across R1, designated as V_{Leakage} 430, so the current sensing element of the ammeter (not shown here), such as the ammeter 344 of FIG. 3, is intrinsic to the current limiter 442. In general (R1+R2) is selected to limit current to a safe level (as per industry standards, such as for example, but not limited to, UL 60950) and R1 is selected to provide a V/A gain compatible with the input voltage range of the voltage measurement mechanism, for example, via an Analog to Digital conversion, as disclosed herein with respect to FIG. 4.

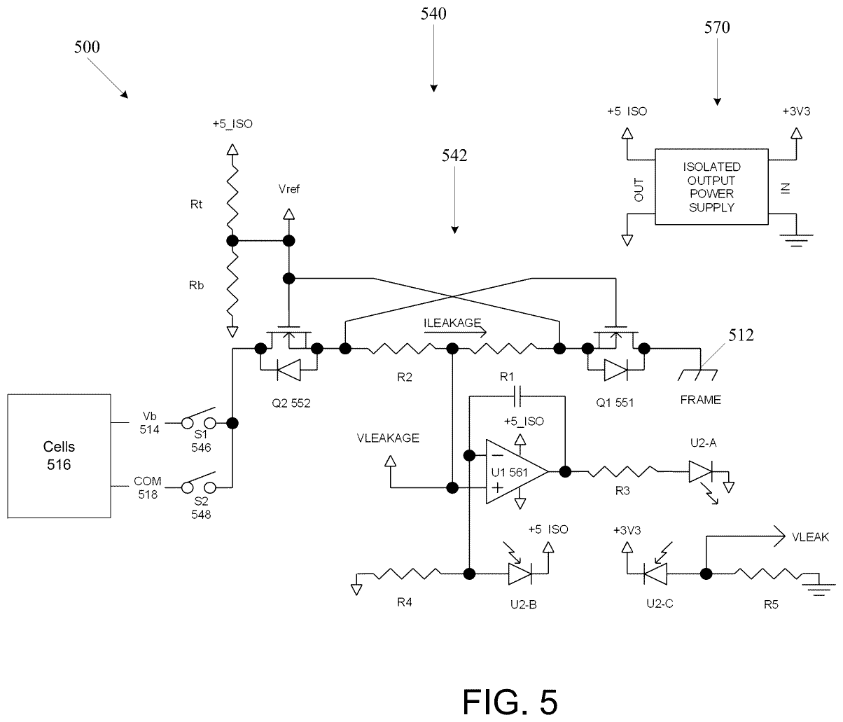

FIG. 5 is a circuit diagram showing an embodiment of a sensing module 540 with a leakage detection mechanism in an electrical energy storage system 500, in accordance with various embodiments. As illustrated in FIG. 5, the electrical energy storage system 500 includes the sensing module 540 that is coupled to a plurality of electrochemical cells 516 that are disposed within a housing frame 512. The sensing module 540 includes a current limiter 542, which may be a bi-directional current limiter that incorporates a current measurement element, in accordance with one or more embodiments herein with respect to FIG. 5. As illustrated, Q1 551, R1, R2 and Q2 552 are connected in a serial arrangement to form the current limiter 542 which electrically connects the frame 512 and the plurality of cells 516, and to the anode Vb 514 or cathode Com 518 of the cells 516 via solid state relays S1 546 and S2 548, in accordance with one or more embodiments. The frame end of R1 is biased to Vref created by a resistive divider Rt and Rb running off a power supply with an isolated output, referred to as isolated output supply 570, as illustrated in FIG. 5. In one or more embodiments, Vref may be set to half the supply voltage and allows for measuring negative currents given a single ended power supply.

As further illustrated in FIG. 5, U1 561 is an amplifier operating from the isolated output supply 570. As illustrated in FIG. 5, the sensing module 540 may include a high-linearity analogue optocoupler U2-A, where photodiodes U2-B and U2-C are well matched, in one or more embodiments. During operation, the voltage across R1, VLEAKAGE, is impressed across R4 by driving U2-A to generate sufficient current in U2-B (where U1, U2-B, R3 and R4 form a servomechanism), in one or more embodiments. The same current may flow through U2-C, thereby generating a voltage supplied to the Analog to Digital (AtoD) input (V_{LEAK}) which may be scaled by the value of R5, in one or more embodiments. In some embodiments, R5 may be set such that the voltage across R5 is half the AtoD input voltage range when no leakage current may be allowed to flow, for example when S1 546 and S2 548 are open.

In one or more embodiments, a processor that is configured to control S1 546, S2 548 and the AtoD converter, may be used to calculate ILEAKAGE by measuring V_{LEAK} with S1 546 and S2 548 open, with S1 546 closed and S2 548 open, and with S1 546 open and S2 548 closed, and a priori knowledge of the values of R1, R4 and R5. Specifically, the sensing module 540 may be configured to detect the leakage current between the plurality of electrochemical cells 516 and the housing frame 512 via the following algorithm, which may include as follows:
1. Measure V_{LEAK} with S1 and S2 open. Call this Vo
2. Measure V_{LEAK} with S1 closed and S2 open. Call this VH
3. Measure V_{LEAK} with S1 open and S2 closed. Call this VL
4. Calculate IH=(VH−Vo)*R4/(R1*R5)
5. Calculate IL=(VL−Vo)*R4/(R1*R5)
6. Declare leakage error if the magnitude of IH or IL exceeds a maximum allowable leakage current threshold

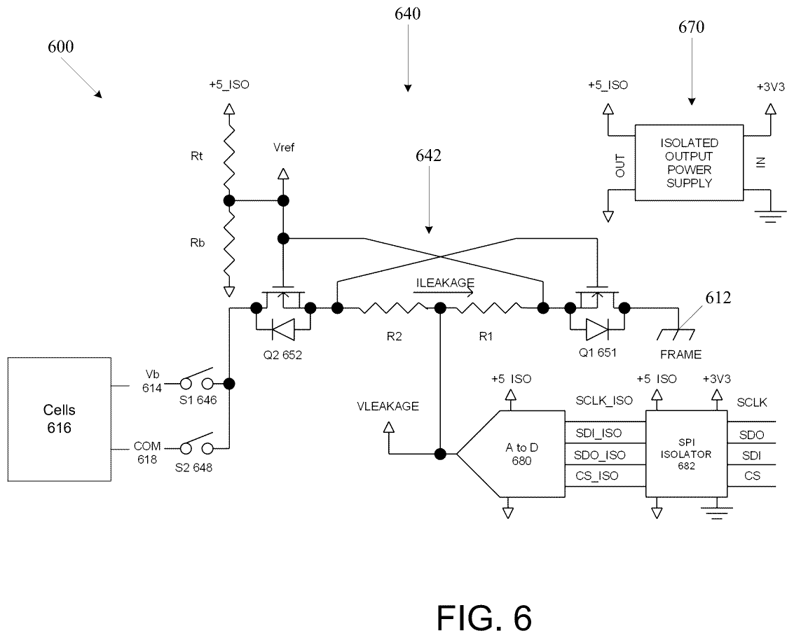

FIG. 6 is a circuit diagram showing another embodiment of a sensing module 640 with a leakage detection mechanism in an electrical energy storage system 600, in accordance with various embodiments. As illustrated in FIG. 6, the electrical energy storage system 600 includes the sensing module 640 that is coupled to a plurality of electrochemical cells 616 that are disposed within a housing frame 612. The sensing module 640 includes a current limiter 642, which may be a bi-directional current limiter that incorporates a current measurement element, in accordance with one or more embodiments herein with respect to FIG. 6. As illustrated, Q1 651, R1, R2 and Q2 652 are connected in a serial arrangement to form the current limiter 642 which electrically connects the frame 612 and the plurality of cells 616, and to the anode Vb 614 or cathode Com 618 of the cells 616 via solid state relays S1 646 and S2 648, in accordance with one or more embodiments. The frame end of R1 is biased to Vref created by a resistive divider Rt and Rb running off a power supply with an isolated output, referred to as isolated output supply 670, as illustrated in FIG. 6. In one or more embodiments, Vref may be set to half the supply voltage and allows for measuring negative currents given a single ended power supply. As further illustrated in FIG. 6, an A to D converter 680 is connected directly to VLEAKAGE and is controlled by a processor via an isolated interface, such as SPI isolator 682.

Examples of selected components for the sensing modules 540 or 640 may include the follow criteria:
Allowable leakage current: 200 uA (Too big? Too small?)
AtoD input range: 0-2.5V (Current processor with 2.5V VREF)
Op Amp: OPA376-Q1 10 picoA input current max. 25 microV max offset current
Optocoupler: HCNR201 7% maximum mismatch between photodiodes
Bias Resistors: Set to 1k (each) for bias voltage of 2.5V
Current limit set to ImA Max (for safety). Vt ∈ [−2.0, −4.0] ⇒R1+R2 =4/1 mA=4k.
Choose R1=3k00 for 3V/mA, thus R2=4k−3k=1k00
Choose R3=100 Ω (lots of current drive for LED)
Choose R4=100k0 (arbitrary)
Set V5 to 1.25 volts when zero leakage current ⇒R5=1/2R4=49k9
All resistors 1% or better. Ideal gain using above values R4/(R1*R5)=667 uA/V at A/D input. Errors are about ±10%.

In some embodiments, linear optocouplers disclosed above may have upwards of 7% mismatch between photodiodes. To eliminate the optocoupler, it may move a differential AtoD converter into the circuit and transmit the AtoD data and control signals via an isolated means. AtoD converters with an SPI interface are readily available, as are SPI isolators, such as SPI isolator 682 to improve accuracy in the measurements, as shown in FIG. 6.

In accordance with various embodiments, an electrical energy storage system, such as electrical energy storage systems 100, 200, 300, 400, 500, and 600, are described with respect to FIGS. 1, 2, 3, 4, 5, and 6, respectively, as disclosed herein. The electrical energy storage systems may include a plurality of electrochemical cells and a housing frame configured to house the plurality of electrochemical cells therewithin. In one or more embodiments, such systems may include a sensing module comprising a current limiter and an ammeter. In one or more embodiments, the current limiter may be electrically coupled to a cathode or an anode of one or more of the plurality of electrochemical cells and the housing frame. In one or more embodiments, the ammeter may be configured to measure a current between the current limiter and the plurality of electrochemical cells.

In one or more embodiments, the sensing module may be configured to detect a leakage between the plurality of electrochemical cells and the housing frame. In one or more embodiments, the sensing module may further include a first relay switch S1 and a second relay switch S2. In one or more embodiments, the current limiter may be connected to the cathode of one or more of plurality of electrochemical cells via S1. In one or more embodiments, the current limiter may be connected to the anode of one or more of plurality of electrochemical cells via S2. In one or more embodiments, each of the plurality of electrochemical cells may be connected to one another in a serial arrangement. In one or more embodiments, S1 may be connected to a first electrochemical cell of the plurality of electrochemical cells and S2 is connected to a second electrochemical cell of the plurality of electrochemical cells.

In one or more embodiments, the current limiter may be a bi-directional current limiter circuit that includes a first depletion-mode metal-oxide-semiconductor field-effect transistor (MOSFET) Q1 and a second depletion-mode MOSFET Q2. In one or more embodiments, the MOSFETs may be N-channel MOSFETs. In one or more embodiments, Q1 includes Q1 source and Q1 gate, Q2 includes Q2 source and Q2 gate, the bi-directional current limiter circuit further includes a first resistor R1 and a second resistor R2, Q1 source is connected in series to Q2 source via R1 and R2, such that Q1 source, R1, R2, and Q2 source are connected in a serial arrangement, Q1 gate is connected to Q2 source, and Q2 gate is connected to Q1 source.

In one or more embodiments, the electrical energy storage systems may further include a reference bias circuit powered by an isolated power supply, wherein the bi-directional current limiter circuit is biased to a reference voltage via the reference bias circuit powered by the isolated power supply. In one or more embodiments, the reference bias circuit may include two resistive dividers Rt and Rb configured to regulate the reference voltage.

In one or more embodiments, the sensing module may be further configured to detect the leakage between the plurality of electrochemical cells and the housing frame via a plurality of leakage voltage measurements performed with S1 and S2 open, with S1 closed and S2 open, and with S1 open and S2 closed.

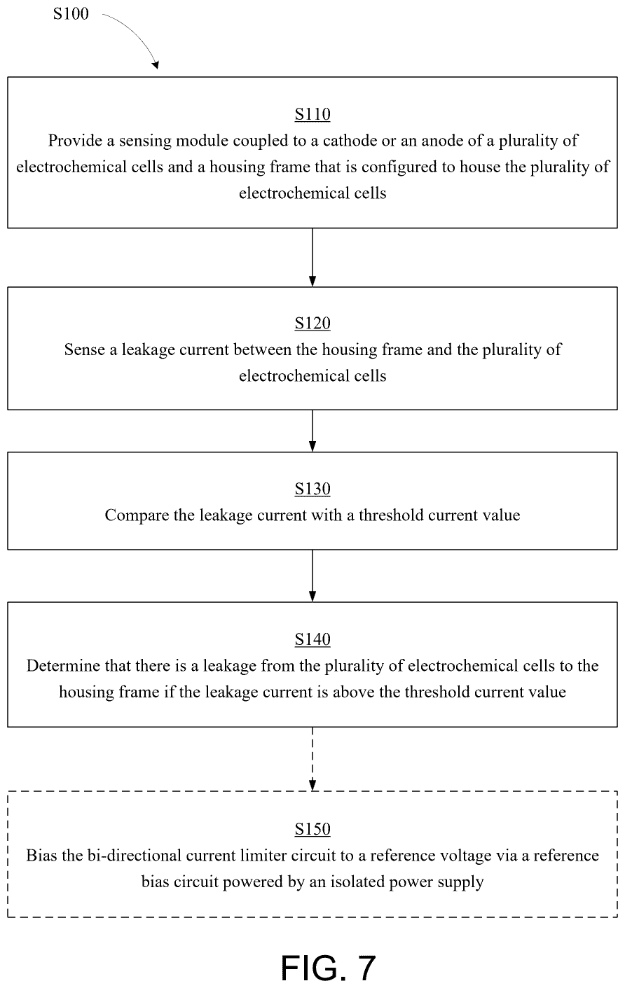

Now referring to FIG. 7, which illustrates a method S100 for detecting a leakage in an electrical energy storage system, such as systems 100, 200, 300, 400, 500, and 600, in accordance with various embodiments. As illustrated in FIG. 7, the method S100 includes, at step S110, providing a sensing module coupled to a cathode or an anode of a plurality of electrochemical cells, such as cells 116, 216, 316, 416, 516 and 616, and a housing frame, such as frames 112, 212, 312, 412, 512, and 612, that is configured to house the plurality of electrochemical cells. In various embodiments, the sensing module may include sensing modules, such as sensing modules 340, 440, 540, and 640. The sensing module may include a current limiter, such as current limiters 342, 442, 542, and 642, a first relay switch S1 and a second relay switch S2, wherein the current limiter is connected to the cathode of the one or more of plurality of electrochemical cells via S1 and to the anode of the one or more of plurality of electrochemical cells via S2, wherein each of the plurality of electrochemical cells are connected to one another in a serial arrangement, wherein S1 is connected to a first electrochemical cell of the plurality of electrochemical cells, and wherein S2 is connected to a second electrochemical cell of the plurality of electrochemical cells.

The method S100 further includes, at step S120, sensing a leakage current between the housing frame and the plurality of electrochemical cells; at step S130, comparing the leakage current with a threshold current value; and at step S140, determining that there is a leakage from the plurality of electrochemical cells to the housing frame if the leakage current is above the threshold current value. In various embodiments of the method S100, the current limiter is a bi- directional current limiter circuit having a first depletion-mode metal-oxide-semiconductor field- effect transistor (MOSFET) Q1 and a second depletion-mode MOSFET Q2. In various embodiments of the method S100, Q1 includes Q1 source and Q1 gate, Q2 includes Q2 source and Q2 gate, the bi-directional current limiter circuit further includes a first resistor R1 and a second resistor R2, Q1 source is connected in series to Q2 source via R1 and R2, such that Q1 source, R1, R2, and Q2 source are connected in a serial arrangement, Q1 gate is connected to Q2 source, and Q2 gate is connected to Q1 source.

The method S100 may optionally further include, at step S150, biasing the bi-directional current limiter circuit to a reference voltage via a reference bias circuit powered by an isolated power supply. In various embodiments of the method S100, the reference bias circuit may include two resistive dividers Rt and Rb configured to regulate the reference voltage. In various embodiments of the method S100, sensing the leakage current between the plurality of electrochemical cells and the housing frame may include performing a plurality of leakage voltage measurements performed with S1 and S2 open, with S1 closed and S2 open, and with S1 open and S2 closed.

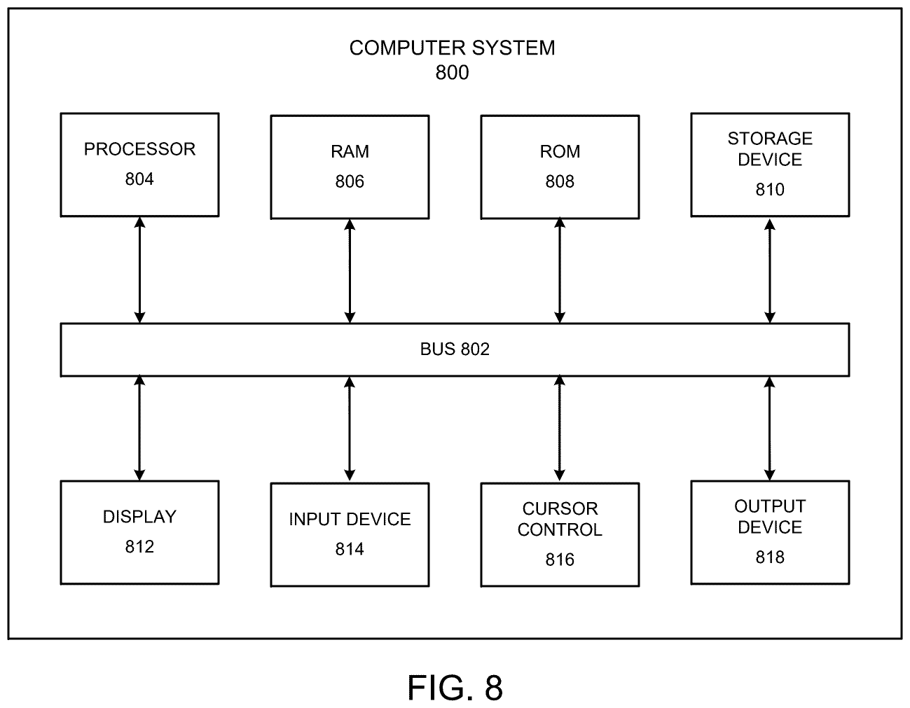

FIG. 8 illustrates a block diagram of a processor (computer system 800) used in the electrical energy storage systems 100, 200, 300, 400, 500, and 600, respectively, of FIGS. 1, 2, 3, 4, 5, and 6, and the method of FIG. 7, in accordance with various embodiments. Computer system 800 may be used as a processor in the electrical energy storage systems 100, 200, 300, 400, 500, and 600, respectively, of FIGS. 1, 2, 3, 4, 5, and 6, and the method of FIG. 7, as described further below, with respect to FIG. 8.

In one or more examples, computer system 800 can include a bus 802 or other communication mechanism for communicating information, and a processor 804 coupled with bus 802 for processing information. In various embodiments, computer system 800 can also include a memory, which can be a random-access memory (RAM) 806 or other dynamic storage device, coupled to bus 802 for determining instructions to be executed by processor 804. Memory also can be used for storing temporary variables or other intermediate information during execution of instructions to be executed by processor 804. In various embodiments, computer system 800 can further include a read only memory (ROM) 808 or other static storage device coupled to bus 802 for storing static information and instructions for processor 804. A storage device 810, such as a magnetic disk or optical disk, can be provided and coupled to bus 802 for storing information and instructions.

In various embodiments, computer system 800 can be coupled via bus 802 to a display 812, such as a cathode ray tube (CRT), liquid crystal display (LCD), or light emitting diode (LED) for displaying information to a computer user. An input device 814, including alphanumeric and other keys, can be coupled to bus 802 for communicating information and command selections to processor 804. Another type of user input device is a cursor control 816, such as a mouse, a joystick, a trackball, a gesture input device, a gaze-based input device, or cursor direction keys for communicating direction information and command selections to processor 804 and for controlling cursor movement on display 812. This input device 814 typically has two degrees of freedom in two axes, a first axis (e.g., x) and a second axis (e.g., y), that allows the device to specify positions in a plane. However, it should be understood that input devices 814 allowing for three-dimensional (e.g., x, y, and z) cursor movement are also contemplated herein.

Consistent with certain implementations of the present teachings, results can be provided by computer system 800 in response to processor 804 executing one or more sequences of one or more instructions contained in RAM 806. Such instructions can be read into RAM 806 from another computer-readable medium or computer-readable storage medium, such as storage device 810. Execution of the sequences of instructions contained in RAM 806 can cause processor 804 to perform the processes described herein. Alternatively, hard-wired circuitry can be used in place of or in combination with software instructions to implement the present teachings. Thus, implementations of the present teachings are not limited to any specific combination of hardware circuitry and software.

The term “computer-readable medium” (e.g., data store, data storage, storage device, data storage device, etc.) or “computer-readable storage medium” as used herein refers to any media that participates in providing instructions to processor 804 for execution. Such a medium can take many forms, including but not limited to, non-volatile media, volatile media, and transmission media. Examples of non-volatile media can include, but are not limited to, optical, solid state, magnetic disks, such as storage device 810. Examples of volatile media can include, but are not limited to, dynamic memory, such as RAM 806. Examples of transmission media can include, but are not limited to, coaxial cables, copper wire, and fiber optics, including the wires that comprise bus 802.

Common forms of computer-readable media include, for example, a floppy disk, a flexible disk, hard disk, magnetic tape, or any other magnetic medium, a CD-ROM, any other optical medium, punch cards, paper tape, any other physical medium with patterns of holes, a RAM, PROM, and EPROM, a FLASH-EPROM, any other memory chip or cartridge, or any other tangible medium from which a computer can read.

In addition to computer readable medium, instructions or data can be provided as signals on transmission media included in a communications apparatus or system to provide sequences of one or more instructions to processor 804 of computer system 800 for execution. For example, a communication apparatus may include a transceiver having signals indicative of instructions and data. The instructions and data are configured to cause one or more processors to implement the functions outlined in the disclosure herein. Representative examples of data communications transmission connections can include, but are not limited to, telephone modem connections, wide area networks (WAN), local area networks (LAN), infrared data connections, NFC connections, optical communications connections, etc.

It should be appreciated that the methodologies described herein, flow charts, diagrams, and accompanying disclosure can be implemented using computer system 800 as a standalone device or on a distributed network of shared computer processing resources such as a cloud computing network.

The methodologies described herein may be implemented by various means depending upon the application. For example, these methodologies may be implemented in hardware, firmware, software, or any combination thereof. For a hardware implementation, the processing unit may be implemented within one or more application specific integrated circuits (ASICs), digital signal processors (DSPs), digital signal processing devices (DSPDs), programmable logic devices (PLDs), field programmable gate arrays (FPGAs), processors, controllers, micro- controllers, microprocessors, electronic devices, other electronic units designed to perform the functions described herein, or a combination thereof.

In various embodiments, the methods of the present teachings may be implemented as firmware and/or a software program and applications written in conventional programming languages such as C, C++, Python, etc. If implemented as firmware and/or software, the embodiments described herein can be implemented on a non-transitory computer-readable medium in which a program is stored for causing a computer to perform the methods described above. It should be understood that the various engines described herein can be provided on a computer system, such as computer system 800, whereby processor 804 would execute the analyses and determinations provided by these engines, subject to instructions provided by any one of, or a combination of, the memory components RAM 806, ROM, 808, or storage device 810 and user input provided via input device 814.

### RECITATION OF EMBODIMENTS

Embodiment 1. An electrical energy storage system, comprising a plurality of electrochemical cells; a housing frame configured to house the plurality of electrochemical cells therewithin; and a sensing module comprising a current limiter and an ammeter, the current limiter electrically coupled to a cathode or an anode of one or more of the plurality of electrochemical cells and the housing frame and the ammeter configured to measure a current between the current limiter and the plurality of electrochemical cells, wherein the sensing module is configured to detect a leakage between the plurality of electrochemical cells and the housing frame.

Embodiment 2. The electrical energy storage system of Embodiment 1, wherein the sensing module further comprises a first relay switch S1 and a second relay switch S2, wherein the current limiter is connected to the cathode of the one or more of plurality of electrochemical cells via S1, and wherein the current limiter is connected to the anode of the one or more of plurality of electrochemical cells via S2.

Embodiment 3. The electrical energy storage system of Embodiment 2, wherein: each of the plurality of electrochemical cells are connected to one another in a serial arrangement, S1 is connected to a first electrochemical cell of the plurality of electrochemical cells, and S2 is connected to a second electrochemical cell of the plurality of electrochemical cells.

Embodiment 4. The electrical energy storage system of any one of Embodiments 1-3, wherein the current limiter is a bi-directional current limiter circuit comprising a first depletion- mode metal-oxide-semiconductor field-effect transistor (MOSFET) Q1 and a second depletion-mode MOSFET Q2.

Embodiment 5. The electrical energy storage system of Embodiment 4, wherein: Q1 comprises Q1 source and Q1 gate, Q2 comprises Q2 source and Q2 gate, the bi-directional current limiter circuit further comprises a first resistor R1 and a second resistor R2, Q1 source is connected in series to Q2 source via R1 and R2, such that Q1 source, R1, R2, and Q2 source are connected in a serial arrangement, Q1 gate is connected to Q2 source, and Q2 gate is connected to Q1 source.

Embodiment 6. The electrical energy storage system of Embodiments 4 or 5, further comprising a reference bias circuit powered by an isolated power supply, wherein the bi-directional current limiter circuit is biased to a reference voltage via the reference bias circuit powered by the isolated power supply.

Embodiment 7. The electrical energy storage system of Embodiment 6, wherein the reference bias circuit comprises two resistive dividers Rt and Rb configured to regulate the reference voltage.

Embodiment 8. The electrical energy storage system of any one of Embodiments 5-7, wherein the sensing module is further configured to detect the leakage between the plurality of electrochemical cells and the housing frame via a plurality of leakage voltage measurements performed with S1 and S2 open, with S1 closed and S2 open, and with S1 open and S2 closed.

Embodiment 9. A method for detecting a leakage in an electrical energy storage system, comprising providing a sensing module coupled to a cathode or an anode of a plurality of electrochemical cells and a housing frame that is configured to house the plurality of electrochemical cells, wherein the sensing module comprises a current limiter, a first relay switch S1 and a second relay switch S2, wherein the current limiter is connected to the cathode of the one or more of plurality of electrochemical cells via S1 and to the anode of the one or more of plurality of electrochemical cells via S2, wherein each of the plurality of electrochemical cells are connected to one another in a serial arrangement, wherein S1 is connected to a first electrochemical cell of the plurality of electrochemical cells, and wherein S2 is connected to a second electrochemical cell of the plurality of electrochemical cells; sensing a leakage current between the housing frame and the plurality of electrochemical cells; comparing the leakage current with a threshold current value; and determining that there is a leakage from the plurality of electrochemical cells to the housing frame if the leakage current is above the threshold current value.

Embodiment 10. The method of Embodiment 9, wherein the current limiter is a bi- directional current limiter circuit comprising a first depletion-mode metal-oxide-semiconductor field-effect transistor (MOSFET) Q1 and a second depletion-mode MOSFET Q2.

Embodiment 11. The method of Embodiment 10, wherein: Q1 comprises Q1 source and Q1 gate, Q2 comprises Q2 source and Q2 gate, the bi-directional current limiter circuit further comprises a first resistor R1 and a second resistor R2, Q1 source is connected in series to Q2 source via R1 and R2, such that Q1 source, R1, R2, and Q2 source are connected in a serial arrangement, Q1 gate is connected to Q2 source, and Q2 gate is connected to Q1 source.

Embodiment 12. The method of Embodiments 10 or 11, further comprising biasing the bi- directional current limiter circuit to a reference voltage via a reference bias circuit powered by an isolated power supply.

Embodiment 13. The method of Embodiment 12, wherein the reference bias circuit comprises two resistive dividers Rt and Rb configured to regulate the reference voltage.

Embodiment 14. The method of any one of Embodiments 9-13, wherein sensing the leakage current between the plurality of electrochemical cells and the housing frame comprises performing a plurality of leakage voltage measurements performed with S1 and S2 open, with S1 closed and S2 open, and with S1 open and S2 closed.

Embodiment 15. A module for detecting a leakage in an electrical vehicle battery, comprising: a sensing circuit coupled to, and configured to detect a leakage between, a plurality of electrochemical cells and a housing frame of the electrical vehicle battery, wherein the housing frame is configured to house the plurality of electrochemical cells therewithin, wherein the sensing circuit comprises a current limiter, a first relay switch S1 and a second relay switch S2, wherein the current limiter is electrically connected to a cathode of one or more of plurality of electrochemical cells via S1, and an anode of the one or more of plurality of electrochemical cells via S2.

Embodiment 16. The module of Embodiment 15, wherein: each of the plurality of electrochemical cells are connected to one another in a serial arrangement, S1 is connected to a first electrochemical cell of the plurality of electrochemical cells, and S2 is connected to a second electrochemical cell of the plurality of electrochemical cells.

Embodiment 17. The module of Embodiments 15 or 16, wherein the current limiter is a bi- directional current limiter circuit comprising a first depletion-mode metal-oxide-semiconductor field-effect transistor (MOSFET) Q1 and a second depletion-mode MOSFET Q2.

Embodiment 18. The module of Embodiment 17, wherein: Q1 comprises Q1 source and Q1 gate, Q2 comprises Q2 source and Q2 gate, the bi-directional current limiter circuit further comprises a first resistor R1 and a second resistor R2, Q1 source is connected in series to Q2 source via R1 and R2, such that Q1 source, R1, R2, and Q2 source are connected in a serial arrangement, Q1 gate is connected to Q2 source, and Q2 gate is connected to Q1 source.

Embodiment 19. The module of Embodiments 17 or 18, further comprising a reference bias circuit powered by an isolated power supply, wherein the bi-directional current limiter circuit is biased to a reference voltage via the reference bias circuit powered by the isolated power supply, and wherein the reference bias circuit comprises two resistive dividers Rt and Rb configured to regulate the reference voltage.

Embodiment 20. The module of any one of Embodiments 15-19, wherein the sensing circuit is further configured to detect the leakage between the plurality of electrochemical cells and the housing frame via a plurality of leakage voltage measurements performed with S1 and S2 open, with S1 closed and S2 open, and with S1 open and S2 closed.

1. An electrical energy storage system, comprising:
a plurality of electrochemical cells;
a housing frame configured to house the plurality of electrochemical cells therewithin; and
a sensing module comprising a current limiter and an ammeter, the current limiter electrically coupled to a cathode or an anode of one or more of the plurality of electrochemical cells and the housing frame and the ammeter configured to measure a current between the current limiter and the plurality of electrochemical cells,
wherein the sensing module is configured to detect a leakage between the plurality of electrochemical cells and the housing frame.

2. The electrical energy storage system of claim 1, wherein the sensing module further comprises a first relay switch S1 and a second relay switch S2,
wherein the current limiter is connected to the cathode of the one or more of plurality of electrochemical cells via S1, and
wherein the current limiter is connected to the anode of the one or more of plurality of electrochemical cells via S2.

3. The electrical energy storage system of claim 2, wherein:
each of the plurality of electrochemical cells are connected to one another in a serial arrangement,
S1 is connected to a first electrochemical cell of the plurality of electrochemical cells, and
S2 is connected to a second electrochemical cell of the plurality of electrochemical cells.

4. The electrical energy storage system of claim 1, wherein the current limiter is a bi- directional current limiter circuit comprising a first depletion-mode metal-oxide-semiconductor field-effect transistor (MOSFET) Q1 and a second depletion-mode MOSFET Q2.

5. The electrical energy storage system of claim 4, wherein:
Q1 comprises Q1 source and Q1 gate,
Q2 comprises Q2 source and Q2 gate,
the bi-directional current limiter circuit further comprises a first resistor R1 and a second resistor R2,
Q1 source is connected in series to Q2 source via R1 and R2, such that Q1 source, R1, R2, and Q2 source are connected in a serial arrangement,
Q1 gate is connected to Q2 source, and
Q2 gate is connected to Q1 source.

6. The electrical energy storage system of claim 4, further comprising:
a reference bias circuit powered by an isolated power supply, wherein the bi-directional current limiter circuit is biased to a reference voltage via the reference bias circuit powered by the isolated power supply.

7. The electrical energy storage system of claim 6, wherein the reference bias circuit comprises two resistive dividers Rt and Rb configured to regulate the reference voltage.

8. The electrical energy storage system of claim 5, wherein the sensing module is further configured to detect the leakage between the plurality of electrochemical cells and the housing frame via a plurality of leakage voltage measurements performed with S1 and S2 open, with S1 closed and S2 open, and with S1 open and S2 closed.

9. A method for detecting a leakage in an electrical energy storage system, comprising:
providing a sensing module coupled to a cathode or an anode of a plurality of electrochemical cells and a housing frame that is configured to house the plurality of electrochemical cells,
wherein the sensing module comprises a current limiter, a first relay switch S1 and a second relay switch S2, wherein the current limiter is connected to the cathode of the one or more of plurality of electrochemical cells via S1 and to the anode of the one or more of plurality of electrochemical cells via S2, wherein each of the plurality of electrochemical cells are connected to one another in a serial arrangement, wherein S1 is connected to a first electrochemical cell of the plurality of electrochemical cells, and wherein S2 is connected to a second electrochemical cell of the plurality of electrochemical cells;
sensing a leakage current between the housing frame and the plurality of electrochemical cells;
comparing the leakage current with a threshold current value; and
determining that there is a leakage from the plurality of electrochemical cells to the housing frame if the leakage current is above the threshold current value.

10. The method of claim 9, wherein the current limiter is a bi-directional current limiter circuit comprising a first depletion-mode metal-oxide-semiconductor field-effect transistor (MOSFET) Q1 and a second depletion-mode MOSFET Q2.

11. The method of claim 10, wherein:
Q1 comprises Q1 source and Q1 gate,
Q2 comprises Q2 source and Q2 gate,
the bi-directional current limiter circuit further comprises a first resistor R1 and a second resistor R2,
Q1 source is connected in series to Q2 source via R1 and R2, such that Q1 source, R1, R2, and Q2 source are connected in a serial arrangement,
Q1 gate is connected to Q2 source, and
Q2 gate is connected to Q1 source.

12. The method of claim 10, further comprising:
biasing the bi-directional current limiter circuit to a reference voltage via a reference bias circuit powered by an isolated power supply.

13. The method of claim 12, wherein the reference bias circuit comprises two resistive dividers Rt and Rb configured to regulate the reference voltage.

14. The method of claim 9, wherein sensing the leakage current between the plurality of electrochemical cells and the housing frame comprises performing a plurality of leakage voltage measurements performed with S1 and S2 open, with S1 closed and S2 open, and with S1 open and S2 closed.

15. A module for detecting a leakage in an electrical vehicle battery, comprising:
a sensing circuit coupled to, and configured to detect a leakage between, a plurality of electrochemical cells and a housing frame of the electrical vehicle battery, wherein the housing frame is configured to house the plurality of electrochemical cells therewithin, wherein the sensing circuit comprises a current limiter, a first relay switch S1 and a second relay switch S2,
wherein the current limiter is electrically connected to a cathode of one or more of plurality of electrochemical cells via S1, and an anode of the one or more of plurality of electrochemical cells via S2.

16. The module of claim 15, wherein:
each of the plurality of electrochemical cells are connected to one another in a serial arrangement,
S1 is connected to a first electrochemical cell of the plurality of electrochemical cells, and
S2 is connected to a second electrochemical cell of the plurality of electrochemical cells.

17. The module of claim 15, wherein the current limiter is a bi-directional current limiter circuit comprising a first depletion-mode metal-oxide-semiconductor field-effect transistor (MOSFET) Q1 and a second depletion-mode MOSFET Q2.

18. The module of claim 17, wherein:
Q1 comprises Q1 source and Q1 gate,
Q2 comprises Q2 source and Q2 gate,
the bi-directional current limiter circuit further comprises a first resistor R1 and a second resistor R2,
Q1 source is connected in series to Q2 source via R1 and R2, such that Q1 source, R1, R2, and Q2 source are connected in a serial arrangement,
Q1 gate is connected to Q2 source, and
Q2 gate is connected to Q1 source.

19. The module of claim 17, further comprising:
a reference bias circuit powered by an isolated power supply, wherein the bi-directional current limiter circuit is biased to a reference voltage via the reference bias circuit powered by the isolated power supply, and wherein the reference bias circuit comprises two resistive dividers Rt and Rb configured to regulate the reference voltage.

20. The module of claim 15, wherein the sensing circuit is further configured to detect the leakage between the plurality of electrochemical cells and the housing frame via a plurality of leakage voltage measurements performed with S1 and S2 open, with S1 closed and S2 open, and with S1 open and S2 closed.
